(19) United States
(12) Patent Application Publication
(10) Pub. No.: US 2021/0098258 A1
(43) Pub. Date: Apr. 1, 2021

(54) METHOD OF MANUFACTURING SEMICONDUCTOR DEVICE, SUBSTRATE PROCESSING APPARATUS, AND RECORDING MEDIUM

(71) Applicant: KOKUSAI ELECTRIC CORPORATION, Tokyo (JP)

(72) Inventors: Motomu DEGAI, Toyama-shi (JP); Hiroshi ASHIHARA, Toyama-shi, Toyama (JP)

(73) Assignee: KOKUSAI ELECTRIC CORPORATION, Tokyo (JP)

(21) Appl. No.: 17/104,244

(22) Filed: Nov. 25, 2020

Related U.S. Application Data
(63) Continuation of application No. PCT/JP2018/020275, filed on May 28, 2018.

(51) Int. Cl. H01L 21/285; C23C 16/02; C23C 16/04; C23C 16/34; C23C 16/455; C23C 16/52; C23C 16/46

(52) U.S. Cl. CPC H01L 21/28562; C23C 16/02; C23C 16/04; C23C 16/46; C23C 16/45527; C23C 16/45553; C23C 16/52; C23C 16/34

(57) ABSTRACT

There is provided a technique that includes: modifying a first surface of a substrate by supplying a modifying gas containing an inorganic ligand to the substrate including the first surface and a second surface different from the first surface; and selectively growing a film on the second surface by supplying a deposition gas to the substrate.

### CROSS-REFERENCE TO RELATED APPLICATION

This application is a Bypass Continuation Application of PCT International Application No. PCT/JP2018/020275, filed on May 28, 2018, the entire contents of which are incorporated herein by reference.

### TECHNICAL FIELD

The present disclosure relates to a method of manufacturing a semiconductor device, a substrate processing apparatus, and a recording medium.

### BACKGROUND

As miniaturization of a large scale integrated circuit (hereinafter, referred to as an LSI) progresses, miniaturization of a patterning technique also progresses. As the patterning technique, for example, a hard mask or the like is used, but it is difficult to apply a method of exposing a resist to separate an etching region and a non-etching region due to the miniaturization of the patterning technique. For this reason, an epitaxial film such as silicon (Si) or silicon germanium (SiGe) is selectively grown and formed on a substrate such as a silicon (Si) wafer.

### SUMMARY

The present disclosure provides a technique capable of selectively forming a film on a substrate.

According to an embodiment of the present disclosure, there is provided a technique that includes: modifying a first surface of a substrate by supplying a modifying gas containing an inorganic ligand to the substrate including the first surface and a second surface different from the first surface; and selectively growing a film on the second surface by supplying a deposition gas to the substrate.

### BRIEF DESCRIPTION OF DRAWINGS

The accompanying drawings, which are incorporated in and constitute a part of the specification, illustrate embodiments of the present disclosure.

FIG. 1 is a top cross-sectional view illustrating a substrate processing apparatus 10 according to an embodiment of the present disclosure.

FIG. 2 is a vertical cross-sectional view illustrating a configuration of a process furnace 202a of the substrate processing apparatus 10 according to an embodiment of the present disclosure.

FIG. 3 is a top cross-sectional view of the process furnace 202a illustrated in FIG. 2.

FIG. 4 is a vertical cross-sectional view illustrating a configuration of a process furnace 202b of the substrate processing apparatus 10 according to an embodiment of the present disclosure.

FIG. 5 is a top cross-sectional view of the process furnace 202b illustrated in FIG. 4.

FIG. 6 is a block diagram illustrating a configuration of a control part of the substrate processing apparatus 10 according to an embodiment of the present disclosure.

FIG. 7A is a diagram illustrating a gas supply timing according to an embodiment of the present disclosure, and FIG. 7B is a diagram illustrating an exemplary modification of FIG. 7A.

FIG. 8A is a model diagram illustrating a state of a surface of a wafer on which a SiO₂ layer and a SiN layer are formed before exposure with a WF₆ gas, FIG. 8B is a model diagram illustrating a state immediately after the surface of the wafer is exposed with the WF₆ gas, and FIG. 8C is a model diagram illustrating a state of the surface of the wafer after exposure with the WF₆ gas.

FIG. 9A is a model diagram illustrating a state of the surface of the wafer immediately after a TiCl₄ gas is supplied, and FIG. 9B is a model diagram illustrating a state of the surface of the wafer after exposure with the TiCl₄ gas, and FIG. 9C is a model diagram illustrating a state of the surface of the wafer immediately after a NH₃ gas is supplied.

FIG. 10A is a model diagram illustrating a state of the surface of the wafer after exposure with the NH₃ gas, and FIG. 10B is a diagram illustrating the surface of the wafer after substrate processing according to an embodiment of the present disclosure is performed.

FIG. 11 is a vertical cross-sectional view illustrating a process furnace 302 of a substrate processing apparatus 300 according to another embodiment of the present disclosure.

FIG. 12 is a top cross-sectional view of the process furnace 302 illustrated in FIG. 11.

FIG. 13A is a diagram illustrating a relationship between the number of film formation cycles and a film thickness of a TiN film formed on the SiN layer, and FIG. 13B is a diagram illustrating a relationship between the number of film formation cycles and a film thickness of a TiN film formed on the SiO₂ layer.

FIG. 14 illustrates a dependence of T_{SiN} on the number of times that pulse supply of WF₆ gas is repeated.

FIG. 15A is a diagram illustrating a relationship among a method of supplying a WF₆ gas, the number of film formation cycles and a film thickness of a TiN film formed on the SiO₂ layer, and FIG. 15B is a diagram illustrating a relationship between the number of film formation cycles and a film thickness of a TiN film formed on each of the SiO₂ layer, a ZrO layer and a HfO layer.

FIG. 16A is a diagram illustrating a film thickness of a SiN film selectively grown on each of the SiN layer and the SiO₂ layer when a film-forming process is performed without performing a modification process, FIG. 16B is a diagram illustrating a film thickness of a SiN film selectively grown on each of the SiN layer and the SiO₂ layer when the film-forming process is performed after the modification process, and FIG. 16C is a diagram illustrating a film thickness of a SiN film selectively grown on each of the SiN layer and the SiO₂ layer when the modification process and the film-forming process are alternately performed twice.

### DETAILED DESCRIPTION

Reference will now be made in detail to various embodiments, examples of which are illustrated in the accompanying drawings. In the following detailed description, numerous specific details are set forth to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Embodiments of the present disclosure will now be described.

Hereinafter, exemplary embodiments of the present disclosure will be described in more detail with reference to the drawings.

### (1) CONFIGURATION OF THE SUBSTRATE PROCESSING APPARATUS

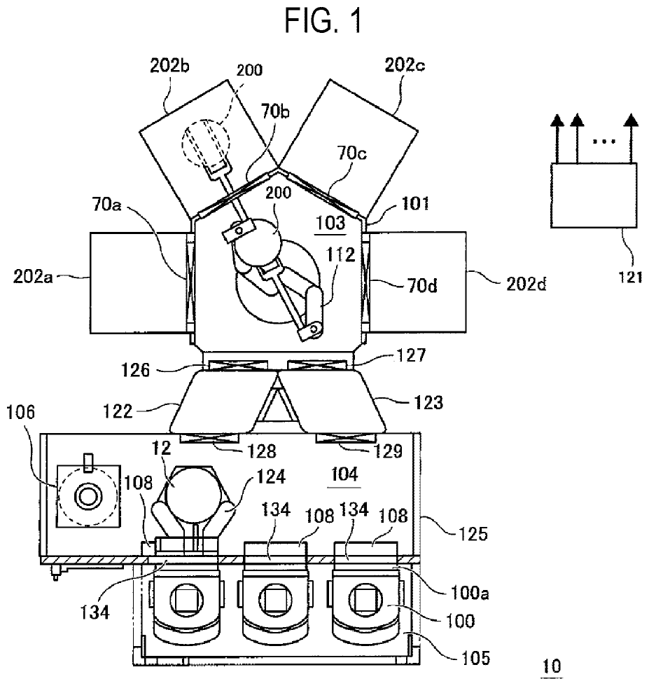

FIG. 1 is a top cross-sectional view of a substrate processing apparatus configured to carry out a method of manufacturing a semiconductor device (hereinafter, simply referred to as a substrate processing apparatus 10). A transfer device of a cluster-type substrate processing apparatus 10 according to the present embodiment is divided into a vacuum side and an atmospheric side. Further, in the substrate processing apparatus 10, front opening unified pods (FOUPs, hereinafter referred to as pods) 100 are used as carriers that transfer wafers 200 as substrates.

### (Vacuum Side Configuration)

As illustrated in FIG. 1, the substrate processing apparatus 10 includes a first transfer chamber 103 which can withstand a pressure (negative pressure) below an atmospheric pressure such as a vacuum state. A housing 101 of the first transfer chamber 103 has, for example, a pentagon in a plane view, and is formed in a box shape with both upper and lower ends closed.

A first substrate transfer device 112 configured to transfer the wafers 200 is installed in the first transfer chamber 103.

Spare chambers (load lock chambers) 122 and 123 are connected to a sidewall at the front side out of five sidewalls of the housing 101 via gate valves 126 and 127 respectively. The spare chambers 122 and 123 are configured so that both a function of loading the wafers 200 and a function of unloading the wafers 200 can be used, and each have a structure capable of withstanding a negative pressure.

A process furnace 202a as a first process unit, a process furnace 202b as a second process unit, a process furnace 202c as a third process unit, and a process furnace 202d as a fourth process unit, in which the substrates are accommodated and desired processing is performed on the accommodated substrates, are connected to four sidewalls at the rear side out of the five sidewalls of the housing 101 of the first transfer chamber 103 while being adjacent to each other via gate valves 70a, 70b, 70c, and 70d respectively.

### (Atmosphere Side Configuration)

A second transfer chamber 104 configured to be capable of transferring the wafers 200 under an atmospheric pressure is connected to the front side of the spare chambers 122 and 123 via gate valves 128 and 129. A second substrate transfer device 124 configured to transfer the wafers 200 is installed at the second transfer chamber 104.

A notch alignment device 106 is installed at the left side of the second transfer chamber 104. The notch alignment device 106 may also be an orientation flat alignment device. In addition, a clean unit configured to supply clean air is installed above the second transfer chamber 104.

Substrate loading/unloading ports 134 configured to load and unload the wafers 200 into and from the second transfer chamber 104, and pod openers 108 are installed at the front side of a housing 125 of the second transfer chamber 104. A load port (TO stage) 105 is installed at the opposite side of the pod openers 108 with the substrate loading/unloading ports 134 interposed therebetween, that is, outside the housing 125. The pod openers 108 each include a closure configured to be capable of opening and closing caps 100a of the pods 100 and closing the substrate loading/unloading ports 134. The wafers 200 can be taken in and out of the pods 100 by opening and closing the caps 100a of the pods 100 placed on the load port 105. Furthermore, the pods 100 are supplied and discharged to the load port 105 by an in-process transfer device (OHT or the like) (not shown).

### (Configuration of the Process Furnace 202a)

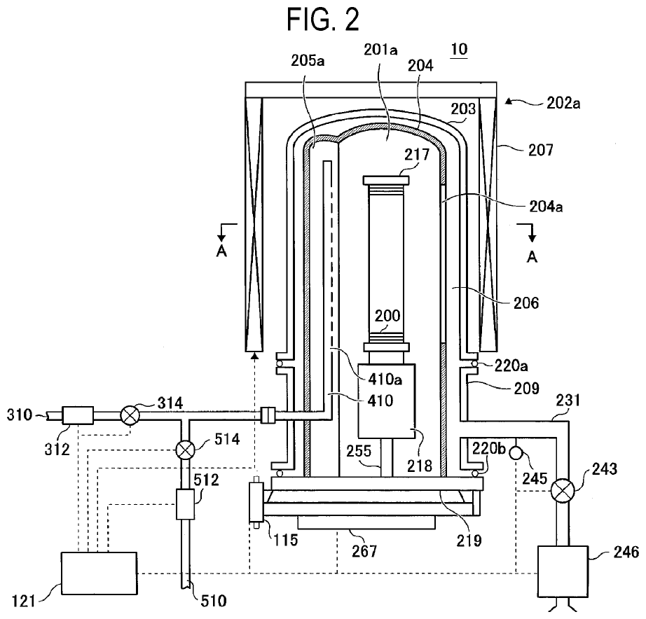

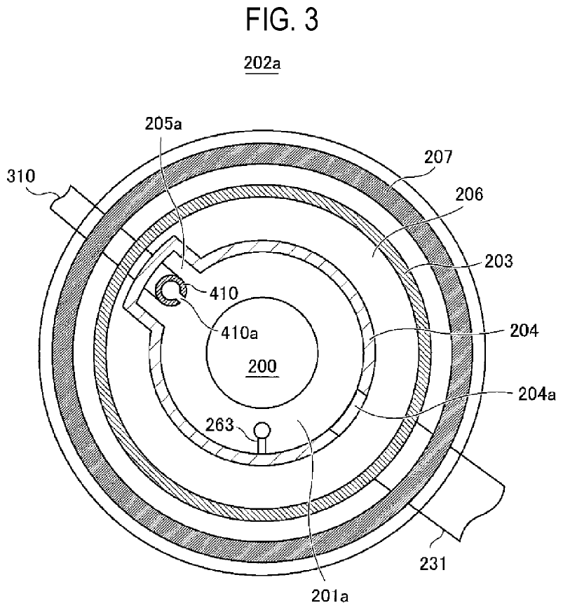

FIG. 2 is a vertical cross-sectional view of the process furnace 202a as the first process unit included in the substrate processing apparatus 10, and FIG. 3 is a top cross-sectional view of the process furnace 202a.

In the present embodiment, an example in which a film-forming process is performed in the process furnace 202b as the second process unit will be described after a modification process is performed in the process furnace 202a as the first process unit, but the same substrate processing may be performed in the process furnace 202c as the third process unit and the process furnace 202d as the fourth process unit.

The process furnace 202a includes a heater 207 as a heating means (a heating mechanism or a heating system). The heater 207 has a cylindrical shape and is supported by a heater base (not shown) as a holding plate to be vertically installed.

An outer tube 203 constituting a reaction vessel (process vessel) is disposed inside the heater 207 to be concentric with the heater 207. The outer tube 203 is made of a heat resistant material, for example, quartz (SiO₂), silicon carbide (SiC) or the like, and has a cylindrical shape with its upper end closed and its lower end opened. A manifold (inlet flange) 209 is disposed below the outer tube 203 in a concentric relationship with the outer tube 203. The manifold 209 is made of metal such as, e.g., stainless steel (SUS), and has a cylindrical shape with its upper and lower ends opened. An O-ring 220a as a seal member is installed between the upper end of the manifold 209 and the outer tube 203. The manifold 209 is supported by the heater base such that the outer tube 203 is vertically installed.

An inner tube 204 constituting the reaction vessel is disposed inside the outer tube 203. The inner tube 204 is made of a heat resistant material, e.g., quartz (SiO₂), silicon carbide (SiC) or the like, and has a cylindrical shape with its upper end closed and its lower end opened. The process vessel (reaction vessel) mainly includes the outer tube 203, the inner tube 204, and the manifold 209. A process chamber 201a as a first process chamber is formed in a hollow cylindrical portion of the process vessel (inside the inner tube 204).

The process chamber 201a is configured to be capable of accommodating wafers 200 as substrates, in such a state that the wafers 200 are arranged in a horizontal posture and in multiple stages along a vertical direction by a boat 217 which will be described hereinbelow.

A nozzle 410 is installed in the process chamber 201a to penetrate a sidewall of the manifold 209 and the inner tube 204. A gas supply pipe 310 is connected to the nozzle 410. However, the process furnace 202a of the present embodiment is not limited to the aforementioned configuration.

A mass flow controller (MFC) 312 which is a flow rate controller (flow rate control part) is installed at the gas supply pipe 310 sequentially from the corresponding upstream side. In addition, a valve 314, which is an opening/closing valve, is installed at the gas supply pipe 310. A gas supply pipe 510, which supplies an inert gas, is connected to the gas supply pipe 310 at the downstream side of the valve 314. An MFC 512 and a valve 514 are installed at the gas supply pipe 510 sequentially from the corresponding upstream side.

The nozzle 410 is connected to a front end portion of the gas supply pipe 310. The nozzle 410 is configured as an L-shaped nozzle. A horizontal portion of the nozzle 410 is formed to penetrate the sidewall of the manifold 209 and the inner tube 204. A vertical portion of the nozzle 410 is formed in a channel-shaped (groove-shaped) spare chamber 205a formed to protrude outward of the inner tube 204 in a radial direction and extend along the vertical direction, and is also formed to extend upward along the inner wall of the inner tube 204 in the spare chamber 205a (upward in the arrangement direction of the wafers 200).

The nozzle 410 is installed to extend from a lower region of the process chamber 201a to an upper region of the process chamber 201a, and a plurality of gas supply holes 410a are formed at the opposite positions of the wafers 200. Thus, a processing gas is supplied from the gas supply holes 410a of the nozzle 410 to the wafers 200. The gas supply holes 410a may be installed in a plural number between the lower portion of the inner tube 204 and the upper portion of the inner tube 204. The respective gas supply holes 410a may have the same aperture area and may be formed at the same aperture pitch. However, the gas supply holes 410a are not limited to the aforementioned configuration. For example, the aperture area may be gradually enlarged from the lower portion of the inner tube 204 to the upper portion of the inner tube 204. Thus, it is possible to make a flow rate of a gas supplied from the gas supply holes 410a more uniform.

The gas supply holes 410a of the nozzle 410 may be formed in a plural number at height positions from the lower portion of the boat 217 to the upper portion of the boat 217 as described hereinbelow. Therefore, the processing gas supplied from the gas supply holes 410a of the nozzle 410 into the process chamber 201a is supplied to the whole region of the wafers 200 accommodated from the lower portion of the boat 217 to the upper portion of the boat 217. The nozzle 410 may be installed to extend from the lower region of the process chamber 201a to the upper region of the process chamber 201a, but may be installed to extend up to near a ceiling of the boat 217.

A modifying gas, which contains an inorganic ligand, as the processing gas, is supplied from the gas supply pipe 310 into the process chamber 201a via the MFC 312, the valve 314, and the nozzle 410. As the modifying gas, it may be possible to use, for example, a fluorine (F)-containing gas containing a ligand which is a first halide and is electrically negative, and tungsten hexafluoride (WF₆) may be used as an example.

An inert gas, for example, a nitrogen (N₂) gas, is supplied from the gas supply pipe 510 into the process chamber 201a via the MFC 512, the valve 514, and the nozzle 410. An example in which the N₂ gas is used as the inert gas will be described below, but a rare gas such as, e.g., an argon (Ar) gas, a helium (He) gas, a neon (Ne) gas, a xenon (Xe) gas or the like, in addition to the N₂ gas, may be used as the inert gas.

A modifying gas supply system as a first gas supply system mainly includes the gas supply pipe 310, the MFC 312, the valve 314, and the nozzle 410, but only the nozzle 410 may be regarded as the modifying gas supply system. The modifying gas supply system may be referred to as a processing gas supply system or simply a gas supply system. When a modifying gas is allowed to flow from the gas supply pipe 310, the modifying gas supply system mainly includes the gas supply pipe 310, the MFC 312, and the valve 314, but the nozzle 410 may be regarded as being included in the modifying gas supply system. Furthermore, an inert gas supply system mainly includes the gas supply pipe 510, the MFC 512, and the valve 514.

In a gas supply method according to the present embodiment, a gas is transferred via the nozzle 410 which is disposed in the spare chamber 205a in annular longitudinal space, defined by the inner wall of the inner tube 204 and end portions of a plurality of wafers 200. Then, the gas is injected from the plurality of gas supply holes 410a formed at the opposite positions of the nozzle 410 from the wafers into the inner tube 204. More specifically, the modifying gas or the like is injected from the gas supply holes 410a of the nozzle 410 in a direction parallel to the surfaces of the wafers 200.

An exhaust hole (exhaust port) 204a is a through-hole formed on the sidewall of the inner tube 204 and at the opposite position of the nozzle 410, and is, for example, a vertically-elongated slit-shaped through-hole. A gas supplied from the gas supply holes 410a of the nozzle 410 into the process chamber 201a and flowing onto the surface of the wafers 200 flows through an exhaust passage 206 including a gap formed between the inner tube 204 and the outer tube 203 via the exhaust hole 204a. Then, the gas flowing through the exhaust passage 206 flows through the exhaust pipe 231 and is discharged to the outside of the process furnace 202a.

The exhaust hole 204a is formed at the opposite position of the wafers 200, and the gas supplied from the gas supply holes 410a to a region near the wafers 200 in the process chamber 201a flows in the horizontal direction and then flows through the exhaust passage 206 via the exhaust hole 204a. The exhaust hole 204a is not limited to being configured as the slit-shaped through-hole but may be configured by a plurality of holes.

An exhaust pipe 231 configured to exhaust an internal atmosphere of the process chamber 201a is installed at the manifold 209. A pressure sensor 245 as a pressure detector (pressure detection part) which detects the internal pressure of the process chamber 201a, an auto pressure controller (APC) valve 243, and a vacuum pump 246 as a vacuum exhaust device are connected to the exhaust pipe 231 sequentially from the corresponding upstream side. The APC valve 243 is configured so that a vacuum exhaust and a vacuum exhaust stop of the interior of the process chamber 201a can be performed by opening and closing the APC valve 243 while operating the vacuum pump 246 and so that the internal pressure of the process chamber 201a can be adjusted by adjusting an opening degree of the APC valve 243 while operating the vacuum pump 246. An exhaust system mainly includes the exhaust hole 204a, the exhaust passage 206, the exhaust pipe 231, the APC valve 243 and the pressure sensor 245. The vacuum pump 246 may be regarded as being included in the exhaust system.

A seal cap 219, which serves as a furnace opening lid configured to be capable of hermetically sealing a lower end opening of the manifold 209, is installed under the manifold 209. The seal cap 219 is configured to make contact with the lower end portion of the manifold 209 from the lower side in the vertical direction. The seal cap 219 is made of metal such as, e.g., stainless steel (SUS) or the like, and is formed in a disc shape. An O-ring 220b, which is a seal member making contact with the lower end portion of the manifold 209, is installed on an upper surface of the seal cap 219. A rotation mechanism 267 configured to rotate the boat 217 which accommodates the wafers 200 is installed at the opposite side of the process chamber 201a in the seal cap 219. A rotary shaft 255 of the rotation mechanism 267, which penetrates the seal cap 219, is connected to the boat 217. The rotation mechanism 267 is configured to rotate the wafers 200 by rotating the boat 217. The seal cap 219 is configured to be vertically moved up and down by a boat elevator 115 which is an elevator mechanism vertically installed outside the outer tube 203. The boat elevator 115 is configured to be capable of loading and unloading the boat 217 into and from the process chamber 201a by moving the seal cap 219 up and down. The boat elevator 115 is configured as a transfer device (transfer mechanism) which transfers the boat 217 and the wafers 200 accommodated in the boat 217 into and out of the process chamber 201a.

The boat 217 serving as a substrate support is configured to support a plurality of wafers 200, e.g., 25 to 200 wafers, in such a state that the wafers 200 are arranged in a horizontal posture along a vertical direction with centers of the wafers 200 aligned with one another. That is, the boat 217 is configured to arrange the wafers 200 in a spaced-apart relationship. The boat 217 is made of a heat resistant material such as quartz or SiC. Heat insulating plates 218 made of a heat resistant material such as quartz or SiC are supported below the boat 217 in a horizontal posture and in multiple stages (not shown). With this configuration, it is difficult for heat generated from the heater 207 to be transferred to the seal cap 219. However, the present embodiment is not limited to the aforementioned configurations. For example, instead of installing the heat insulating plates 218 below the boat 217, a heat insulating tube as a tubular member made of a heat resistant material such as quartz or SiC may be installed under the boat 217.

As illustrated in FIG. 3, a temperature sensor 263 serving as a temperature detector is installed in the inner tube 204. Based on temperature information detected by the temperature sensor 263, an amount of electric power supplied to the heater 207 is adjusted such that the interior of the process chamber 201a has a desired temperature distribution. Similar to the nozzle 410, the temperature sensor 263 is formed in an L shape. The temperature sensor 263 is installed along the inner wall of the inner tube 204.

### (Configuration of the Process Furnace 202b)

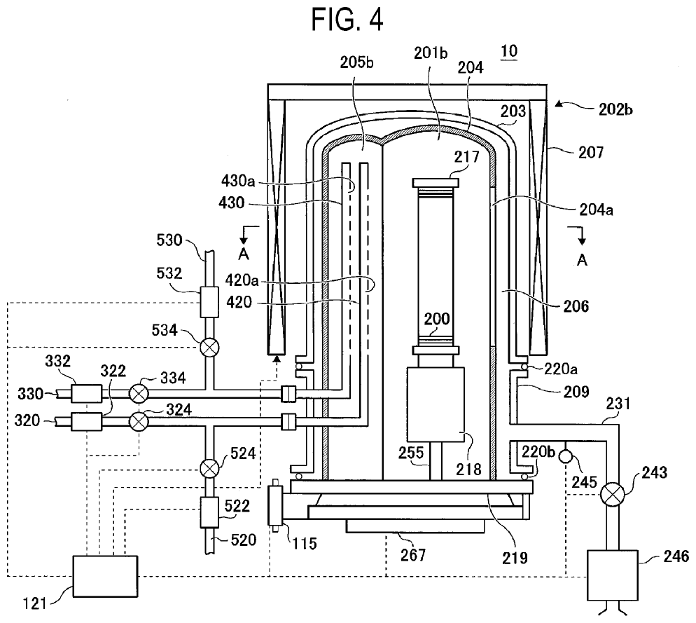

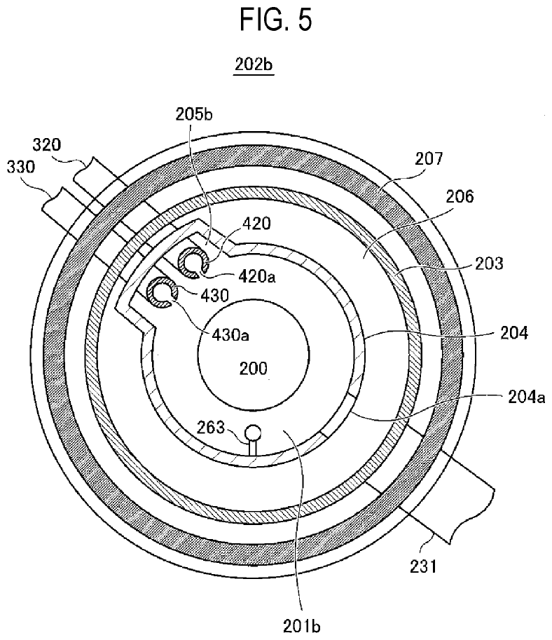

FIG. 4 is a vertical cross-sectional view of the process furnace 202b as the second process unit included in the substrate processing apparatus 10, and FIG. 5 is a top cross-sectional view of the process furnace 202b.

The process furnace 202b according to the present embodiment is different from the aforementioned process furnace 202a in configuration in the process chamber 201a. In the process furnace 202b, only parts different from the aforementioned process furnace 202a will be described below and explanation of the same parts will be omitted. The process furnace 202b includes a process chamber 201b as a second process chamber.

Nozzles 420 and 430 are installed in the process chamber 201b to penetrate a sidewall of the manifold 209 and the inner tube 204. Gas supply pipes 320 and 330 are respectively connected to the nozzles 420 and 430. However, the process furnace 202b of the present embodiment is not limited to the aforementioned configurations.

MFCs 322 and 332 are installed at the gas supply pipes 320 and 330 sequentially from the corresponding upstream sides, respectively. In addition, valves 324 and 334 are installed in the gas supply pipes 320 and 330, respectively. Gas supply pipes 520 and 530, which supply an inert gas, are respectively connected to the gas supply pipes 320 and 330 at the downstream side of the valves 324 and 334. MFCs 522 and 532 and valves 524 and 534 are installed at the gas supply pipes 520 and 530 sequentially from the corresponding upstream sides, respectively.

The nozzles 420 and 430 are respectively connected to front end portions of the gas supply pipes 320 and 330. The nozzles 420 and 430 are each configured as an L-shaped nozzle. Horizontal portions of the nozzles 420 and 430 are formed to penetrate the sidewall of the manifold 209 and the inner tube 204. Vertical portions of the nozzles 420 and 430 are formed in a channel-shaped (groove-shaped) spare chamber 205b formed to protrude outward of the inner tube 204 in a radial direction and extend along the vertical direction, and is also formed to extend upward along the inner wall of the inner tube 204 in the spare chamber 205b (upward in the arrangement direction of the wafers 200).

The nozzles 420 and 430 are installed to extend from a lower region of the process chamber 201b to an upper region of the process chamber 201b, and a plurality of gas supply holes 420a and 430a are respectively formed at the opposite positions of the wafers 200.

The gas supply holes 420a and 430a of the nozzles 420 and 430 may be formed in a plural number at height positions from the lower portion to the upper portion of the boat 217 as described hereinbelow. Therefore, the processing gas supplied from the gas supply holes 420a and 430a of the nozzles 420 and 430 into the process chamber 201b is supplied to the whole region of the wafers 200 accommodated from the lower portion to the upper portion of the boat 217.

A precursor gas as a deposition gas, as the processing gas, is supplied from the gas supply pipe 320 into the process chamber 201b via the MFC 322, the valve 324, and the nozzle 420. As the precursor gas, it may be possible to use, for example, a Cl-containing gas containing chlorine (Cl) containing a ligand which is a second halide and is electrically negative, and a titanium tetrachloride (TiCl₄) gas may be used as an example.

A reaction gas reacting with the precursor gas as the deposition gas, as the processing gas, is supplied from the gas supply pipe 330 into the process chamber 201b via the MFC 332, the valve 334, and the nozzle 430. As the reaction gas, it may be possible to use, for example, a N-containing gas containing nitrogen (N), and an ammonia (NH₃) gas may be used as an example.

An inert gas, for example, a nitrogen (N₂) gas, is supplied from the gas supply pipes 520 and 530 into the process chamber 201b via the MFCs 522 and 532, the valves 524 and 534, and the nozzles 420 and 430. An example in which the N₂ gas is used as the inert gas will be described below, but a rare gas such as, e.g., an argon (Ar) gas, a helium (He) gas, a neon (Ne) gas, a xenon (Xe) gas or the like, in addition to the N₂ gas, may be used as the inert gas.

A deposition gas supply system as a second gas supply system mainly includes the gas supply pipes 320 and 330, the MFCs 322 and 332, the valves 324 and 334, and the nozzles 420 and 430, but only the nozzles 420 and 430 may be regarded as the deposition gas supply system. The deposition gas supply system may be referred to as a processing gas supply system or simply a gas supply system. When the precursor gas is allowed to flow from the gas supply pipe 320, a precursor gas supply system mainly includes the gas supply pipe 320, the MFC 322, and the valve 324, but the nozzle 420 may be regarded as being included in the precursor gas supply system. Further, when the reaction gas is allowed to flow from the gas supply pipe 330, a reaction gas supply system mainly includes the gas supply pipe 330, the MFC 332, and the valve 334, but the nozzle 430 may be regarded as being included in the reaction gas supply system. When a nitrogen-containing gas is supplied as the reaction gas from the gas supply pipe 330, the reaction gas supply system may also be referred to as a nitrogen-containing gas supply system. In addition, an inert gas supply system mainly includes the gas supply pipes 520 and 530, the MFCs 522 and 532, and the valves 524 and 534.

### (Configuration of the Control Part)

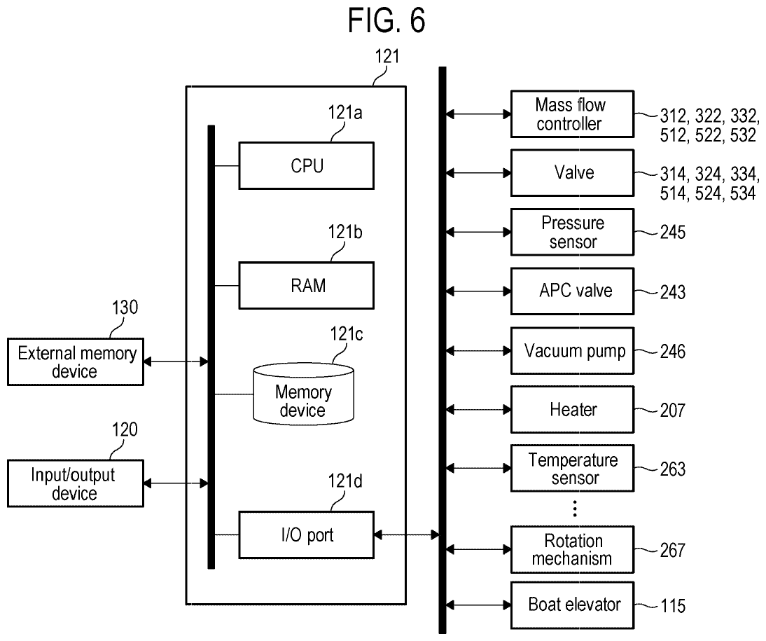

As illustrated in FIG. 6, a controller 121, which is a control part (control means), may be configured as a computer including a central processing unit (CPU) 121a, a random access memory (RAM) 121b, a memory device 121c, and an I/O port 121d. The RAM 121b, the memory device 121c and the I/O port 121d are configured to exchange data with the CPU 121a via an internal bus. An input/output device 120 formed of, e.g., a touch panel or the like, is connected to the controller 121.

The memory device 121c includes, for example, a flash memory, a hard disk drive (HDD), or the like. A control program that controls operations of a substrate processing apparatus, a process recipe in which sequences and conditions of a method of manufacturing a semiconductor device as described hereinbelow and the like are specified, or the like is readably stored in the memory device 121c. The process recipe functions as a program combined to cause the controller 121 to execute each process (each step) in the method of manufacturing a semiconductor device, as described hereinbelow, to obtain a predetermined result. Hereinafter, the process recipe, the control program, and the like will be generally and simply referred to as a “program.” When the term “program” is used herein, it may indicate a case of including only the process recipe, a case of including only the control program, or a case of including combination of the process recipe and the control program. The RAM 121b is configured as a memory area (work area) in which a program, data or the like read by the CPU 121a is temporarily stored.

The I/O port 121d is connected to the MFCs 312, 322, 332, 512, 522 and 532, the valves 314, 324, 334, 514, 524 and 534, the pressure sensor 245, the APC valve 243, the vacuum pump 246, the heater 207, the temperature sensor 263, the rotation mechanism 267, the boat elevator 115 and the gate valves 70a to 70d respectively included in the process furnaces 202a and 202b described above, the first substrate transfer device 112, and the like.

The CPU 121a is configured to read the control program from the memory device 121c and execute the same. The CPU 121a is also configured to read the recipe and the like from the memory device 121c according to an input of an operation command from the input/output device 120. In addition, the CPU 121a is configured to control, according to the contents of the recipe thus read, the flow rate adjusting operation of various kinds of gases by the MFCs 312, 322, 332, 512, 522 and 532, the opening/closing operation of the valves 314, 324, 334, 514, 524 and 534, the opening/closing operation of the APC valve 243, the pressure regulating operation performed by the APC valve 243 based on the pressure sensor 245, the temperature adjusting operation performed by the heater 207 based on the temperature sensor 263, the driving and stopping of the vacuum pump 246, the operation of rotating the boat 217 with the rotation mechanism 267 and adjusting the rotation speed of the boat 217, the operation of moving the boat 217 up or down with the boat elevator 115, the operation of accommodating the wafers 200 in the boat 217, and the like.

The controller 121 may be configured by installing, on the computer, the aforementioned program stored in an external memory device 130 (for example, a magnetic tape, a magnetic disc such as a flexible disc or a hard disc, an optical disc such as a CD or DVD, a magneto-optical disc such as a MO, or a semiconductor memory such as a USB memory or a memory card). The memory device 121c or the external memory device 130 is configured as a computer-readable recording medium. Hereinafter, the memory device 121c and the external memory device 130 will be generally and simply referred to as a “recording medium.” In the present disclosure, the term “recording medium” may indicate a case of including only the memory device 121c, a case of including only the external memory device 130, or a case of including both the memory device 121c and the external memory device 130. Furthermore, the program may be supplied to the computer by using a communication means such as the Internet or a dedicated line, instead of using the external memory device 130.

### (2) SUBSTRATE PROCESSING

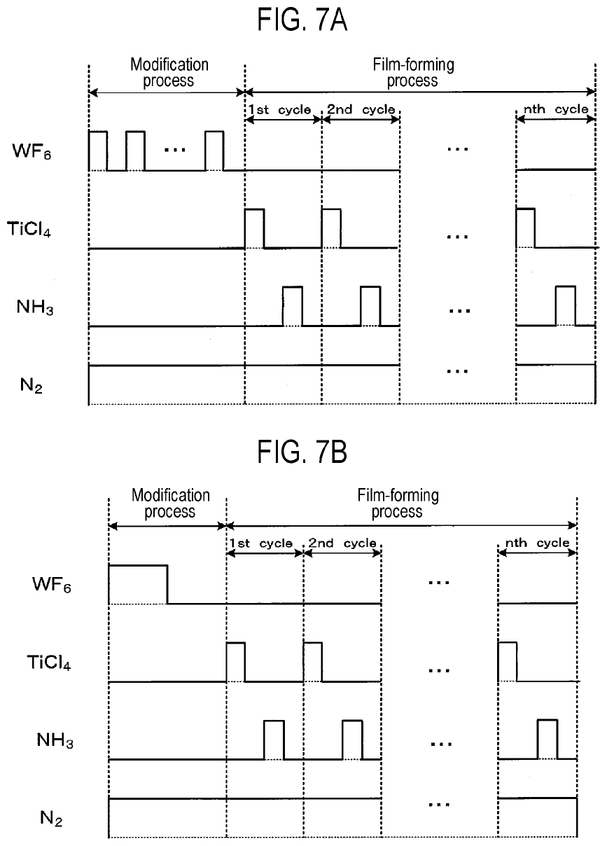

An example of a process of forming a titanium nitride (TiN) film on a SiN layer on a wafer 200 including a silicon oxide (SiO₂) layer as a first surface and the silicon nitride (SiN) layer as a second surface different from the first surface, which is a process for manufacturing a semiconductor device, will be described with reference to FIG. 7A. In this process, after a step of modifying the surface of the SiO₂ layer on the wafer 200 is performed in the process furnace 202a, a step of selectively growing the TiN film on the SiN layer on the wafer 200 is performed in the process furnace 202b. In FIG. 7A, the loading/unloading operation between the process furnace 202a and the process furnace 202b is omitted. In the following descriptions, the operations of the respective parts constituting the substrate processing apparatus 10 are controlled by the controller 121.

The substrate processing (a process of manufacturing a semiconductor device) according to the present embodiment includes: a step of supplying a tungsten hexafluoride (WF₆) gas as a modifying gas containing an inorganic ligand to a wafer 200 including a SiO₂ layer as a first surface and a SiN layer as a second surface to modify the surface of the SiO₂ layer; and a step of supplying a TiCl₄ gas as a precursor gas and a NH₃ gas as a reaction gas, as deposition gases, to the wafer 200 to selectively grow a TiN film on the surface of the SiN layer.

Further, the step of modifying the surface of the SiO₂ layer on the surface of the wafer 200 may be performed multiple times. The step of modifying the surface of the SiO₂ layer on the surface of the wafer 200 may be referred to as a surface modification process or simply a modification process. In addition, the step of selectively growing the TiN film on the surface of the SiN layer on the surface of the wafer 200 may be referred to as a film-forming process.

When the term “wafer” is used herein, it may refer to “a wafer itself” or “a laminated body of a wafer and a predetermined layer or film formed on the surface of the wafer”. In addition, when the phrase “a surface of a wafer” is used herein, it may refer to “a surface of a wafer itself” or “a surface of a predetermined layer or film formed on a wafer”. Further, when the term “substrate” is used herein, it may be synonymous with the term “wafer.”

### A. Modification Process (Modification Processing Step)

First, a wafer 200 having a SiO₂ layer and a SiN layer on its surface is loaded into the process furnace 202a as the first process unit, in which a modification process is performed to form F termination on a surface of the SiO₂ layer on the wafer 200.

### (Wafer Loading)

In a case where a plurality of wafers 200 is charged on the boat 217 (wafer charging), as illustrated in FIG. 2, the boat 217 supporting the plurality of wafers 200 is lifted up by the boat elevator 115 and is loaded into the process chamber 201a (boat loading). In this state, the seal cap 219 seals the lower end opening of the outer tube 203 via the O-ring 220.

### (Pressure Regulation and Temperature Adjustment)

The interior of the process chamber 201a is vacuum-exhausted by the vacuum pump 246 to reach a desired pressure (degree of vacuum). In this operation, the internal pressure of the process chamber 201a is measured by the pressure sensor 245. The APC valve 243 is feedback-controlled based on the measured pressure information (pressure regulation). The vacuum pump 246 may be continuously activated at least until the processing of the wafers 200 is completed. Further, the interior of the process chamber 201a is heated by the heater 207 to a desired temperature. In this operation, the amount of electric power supplied to the heater 207 is feedback-controlled based on the temperature information detected by the temperature sensor 263 such that the interior of the process chamber 201a has a desired temperature distribution (temperature adjustment). The heating of the interior of the process chamber 201a by the heater 207 may be continuously performed at least until the processing of the wafers 200 is completed.

### A-1: [Modifying Gas Supply Step]

### (WF₆ Gas Supply)

The valve 314 is opened to allow a WF₆ gas as a modifying gas to flow through the gas supply pipe 310. The flow rate of the WF₆ gas is adjusted by the MFC 312. The WF₆ gas is supplied from the gas supply hole 410a of the nozzle 410 into the process chamber 201a and is exhausted from the exhaust pipe 231. At this time, the WF₆ gas is supplied to the wafer 200. In parallel with this, the valve 514 is opened to allow an inert gas such as a N₂ gas to flow through the gas supply pipe 510. The flow rate of the N₂ gas flowing through the gas supply pipe 510 is adjusted by the MFC 512. The N₂ gas is supplied into the process chamber 201a together with the WF₆ gas and is exhausted from the exhaust pipe 231.

At this time, the internal pressure of the process chamber 201a may be set at a pressure which falls within a range of, for example, 1 to 1,000 Pa, by adjusting the APC valve 243. The supply flow rate of the WF₆ gas controlled by the MFC 312 may be set at a flow rate which falls within a range of, for example, 1 to 1,000 sccm. The supply flow rate of the N₂ gas controlled by the MFC 512 may be set at a flow rate which falls within a range of, for example, 100 to 10,000 sccm. The time, during which the WF₆ gas is supplied to the wafer 200, may be set at a time which falls within a range of, for example, 1 to 3,600 seconds. At this time, the temperature of the heater 207 is set such that the temperature of the wafer 200 becomes a temperature which falls within a range of, 30 to 300 degrees C., 30 to 250 degrees C. in some embodiments, or 50 to 200 degrees C. in some embodiments. For example, 30 to 300 degrees C. may refer to 30 degrees C. or higher and 300 degrees C. or lower. Hereinafter, the same applies to other numerical ranges. When the temperature of the wafer 200 is set higher than 30 degrees C., the reaction between the SiO₂ layer and the fluorine component (F) contained in the WF₆ gas occurs to form halogen termination on the SiO₂ layer, but when the temperature of the wafer 200 is set lower than 30 degrees C., the WF₆ gas may not react with the SiO₂ layer on the surface of the wafer 200 and the halogen termination may not be formed on the SiO₂ layer. When the temperature of the wafer 200 is set higher than 300 degrees C., the WF₆ gas may be significantly decomposed.

The gases flowing through the process chamber 201a at this time are the WF₆ gas and the N₂ gas. The bond on the surface of the wafer 200 is broken and F contained in the WF₆ gas is bonded by the supply of the WF₆ gas to form the halogen termination on the SiO₂ layer on the surface of the wafer 200. At this time, no halogen termination is formed on the SiN layer on the surface of the wafer 200.

After a lapse of a predetermined time from the start of the supply of the WF₆ gas, the valve 314 of the gas supply pipe 310 is closed to stop the supply of the WF₆ gas.

### A-2: [Purge Step]

### (Residual Gas Removal)

Next, when the supply of the WF₆ gas is stopped, a purge process is performed to exhaust the gas in the process chamber 201a. At this time, the interior of the process chamber 201a is vacuum-exhausted by the vacuum pump 246 while keeping the APC valve 243 of the exhaust pipe 231 opened, and the unreacted WF₆ gas or the WF₄ gas after the surface of the SiO₂ layer is halogen-terminated, which remains within the process chamber 201a, is removed from the interior of the process chamber 201a. At this time, the supply of the N₂ gas into the process chamber 201a is maintained while keeping the valve 514 opened. The N₂ gas acts as a purge gas. This makes it possible to enhance an effect of removing the unreacted WF₆ gas or the WF₄ gas remaining within the process chamber 201a from the interior of the process chamber 201a.

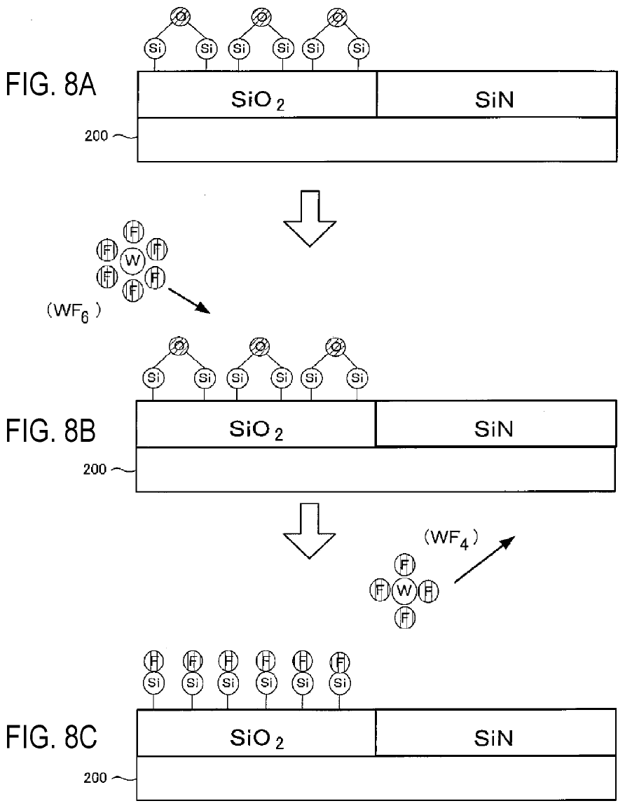

FIGS. 8A to 8C show a state in which halogen termination is formed on the SiO₂ layer and is not formed on the SiN layer. FIG. 8A is a model diagram showing a state of a surface of a wafer 200 on which the SiO₂ layer and the SiN layer are formed before exposure with the WF₆ gas, FIG. 8B is a model diagram showing a state immediately after the surface of the wafer 200 is exposed with the WF₆ gas, and FIG. 8C is a model diagram showing a state of the surface of the wafer 200 after exposure with the WF₆ gas.

Referring to FIG. 8C, it can be seen that the surface of the SiO₂ layer on the wafer 200 is terminated (halogen-terminated) by a fluorine component on the surface of the wafer 200 after exposure with the WF₆ gas. Further, it can be seen that the surface of the SiN layer on the wafer 200 is not terminated (halogen-terminated) by the fluorine component. That is, when the WF₆ gas is exposed, the F molecule of WF₆ is desorbed and adsorbed on the SiO₂ layer, and thus the SiO₂ layer is coated with F to produce a water-repellent effect.

### (Performing a Predetermined Number of Times)

A cycle which sequentially performs the modifying gas supply step and the purge step described above is implemented once or more (a predetermined number of times (n times)), whereby the surface of the SiO₂ layer formed on the wafer 200 is halogen-terminated. Further, the surface of the SiN layer formed on the wafer 200 is not halogen-terminated.

### (After-Purge and Atmospheric Pressure Return)

The N₂ gas is supplied from the gas supply pipe 510 into the process chamber 201a and is exhausted from the exhaust pipe 231. The N₂ gas acts as a purge gas. Thus, the interior of the process chamber 201a is purged with an inert gas and the gas or the byproduct, which remains within the process chamber 201a, is removed from the interior of the process chamber 201a (after-purge). Thereafter, the internal atmosphere of the process chamber 201a is substituted by an inert gas (inert gas substitution). The internal pressure of the process chamber 201a is returned to an atmospheric pressure (atmospheric pressure return).

### (Wafer Unloading)

Next, the seal cap 219 is moved down by the boat elevator 115 to open the lower end of the outer tube 203. Then, the modified wafers 200 supported on the boat 217 are unloaded from the lower end of the outer tube 203 to the outside of the outer tube 203 (boat unloading). Thereafter, the modified wafers 200 are discharged from the boat 217 (wafer discharging).

### B. Film-Forming Process (Selective Growth Step)

Next, the wafer 200 modified in the process furnace 202a is loaded into the process furnace 202b as the second process unit. Then, the interior of the process chamber 201b is adjusted in pressure and temperature to have a desired pressure and a desired temperature distribution, and the film-forming process is performed. This process differs from the process in the process furnace 202a described above only in the gas supply step. Therefore, only parts different from the process in the process furnace 202a described above will be described below, and the same parts will be omitted.

### B-1: [First Step]

### (TiCl₄ Gas Supply)

The valve 324 is opened to allow a TiCl₄ gas, which is a precursor gas, to flow through the gas supply pipe 320. The flow rate of the TiCl₄ gas is adjusted by the MFC 322. The TiCl₄ gas is supplied from the gas supply hole 420a of the nozzle 420 into the process chamber 201b and is exhausted from the exhaust pipe 231. At this time, the TiCl₄ gas is supplied to the wafer 200. In parallel with this, the valve 524 is opened to allow an inert gas such as a N₂ gas to flow through the gas supply pipe 520. The flow rate of the N₂ gas flowing through the gas supply pipe 520 is adjusted by the MFC 522. The N₂ gas is supplied into the process chamber 201b together with the TiCl₄ gas and is exhausted from the exhaust pipe 231. At this time, the valve 534 is opened to allow a N₂ gas flows through the gas supply pipe 530, thus preventing the TiCl₄ gas from entering the nozzle 430. The N₂ gas is supplied into the process chamber 201b via the gas supply pipe 330 and the nozzle 430 and is exhausted from the exhaust pipe 231.

At this time, the internal pressure of the process chamber 201b may be set at a pressure which falls within a range of, for example, 1 to 1,000 Pa, for example, 100 Pa, by adjusting the APC valve 243. The supply flow rate of the TiCl₄ gas controlled by the MFC 322 may be set at a flow rate which falls within a range of, for example, 0.1 to 2 slm. The supply flow rates of the N₂ gas controlled by the MFCs 522 and 532 may be set at a flow rate which falls within a range of, for example, 1 to 10 slm, respectively. The time, during which the TiCl₄ gas is supplied to the wafer 200, may be set at a time which falls within a range of, for example, 0.1 to 200 seconds. At this time, the temperature of the heater 207 may be set such that the temperature of the wafer 200 becomes a temperature which falls within a range of, for example, 100 to 600 degrees C., 200 to 500 degrees C. in some embodiments, or 200 to 400 degrees C. in some embodiments.

The gases flowing through the process chamber 201b at this time are the TiCl₄ gas and the N₂ gas. The TiCl₄ gas is not adsorbed on the SiO₂ layer whose surface is halogen-terminated at the modification processing step described above, but is adsorbed on the SiN layer. Since halogen (Cl) contained in the TiCl₄ gas and halogen (F) on the SiO₂ layer are respectively electrically negative ligands, they become repulsive factors which are difficult to adsorb. That is, the incubation time becomes prolonged on the SiO₂ layer, and thus a TiN film can be selectively grown on a surface other than the SiO₂ layer. In the present disclosure, the incubation time refers to a time until the film starts to grow on the surface of the wafer.

In the present disclosure, when a thin film is selectively formed on a specific wafer surface, the precursor gas may be adsorbed on a wafer surface on which the film is not desired to be formed and unintended film formation may occur. This is a breaking of selectivity. This breaking of selectivity is likely to occur when a probability of adsorption of precursor gas molecules on the wafer is high. In other words, lowering the probability of adsorption of precursor gas molecules on the wafer on which the film is not desired to be formed directly leads to an improvement of selectivity.

The adsorption of the precursor gas on the wafer surface is brought about by electrical interaction between the precursor molecules and the wafer surface when the precursor gas stays on the wafer surface for a certain period of time. That is, the probability of adsorption depends on both an exposure density of the precursor gas or its decomposition product to the wafer and an electrochemical factor of the wafer itself. In the present disclosure, the electrochemical factor of the wafer itself often refers to, for example, surface defects at atomic levels, or electrification by polarization, electric field, or the like. That is, in a case where the electrochemical factor on the wafer surface and the precursor gas are easily attracted to each other, it can be said that the adsorption is likely to occur.

In the related art of a semiconductor film-forming process, the selective film-forming process has been realized by a method in which the wafer is suppressed from staying in a place where the adsorption easily occurs as much as possible by lowering the pressure of the precursor gas or increasing the gas flow velocity on the precursor gas side. However, as the surface area of semiconductor devices has increased according to evolution of miniaturization or three-dimensionalization, technical evolution has been achieved in the direction of increasing the exposure amount of the precursor gas to the wafer. In recent years, a method of obtaining high step coverage for a fine pattern having a large surface area by a method which alternately supplies a gas has become mainstream. That is, it is difficult to achieve the purpose of selectively forming a film by countermeasures on the precursor gas side.

Further, in semiconductor devices, various thin films such as a Si or SiO₂ film, a SiN film, and a metal film are used, and particularly, the control of selective growth properties in a SiO film, which is one of the most widely used materials, greatly contributes to increasing a margin or a degree of freedom in device processing.

That is, a material containing a molecule having strong adsorbability to an oxide film may be used as the modifying gas that modifies the surface of the SiO₂ layer on the wafer 200. In addition, a material which does not etch an oxide film even in a case where the oxide film is exposed to the material at a low temperature may be used as the modifying gas that modifies the surface of the SiO₂ layer on the wafer 200.

### B-2: [Second Step]

### (Residual Gas Removal)

After the Ti-containing layer is formed, the valve 324 is closed to stop the supply of the TiCl₄ gas.

Then, the unreacted TiCl₄ gas, the TiCl₄ gas contributed to the formation of the Ti-containing layer, or the reaction byproduct, which remains within the process chamber 201b, is removed from the interior of the process chamber 201b.

### B-3: [Third Step]

### (NH₃ Gas Supply)

After removing the residual gas within the process chamber 201b, the valve 334 is opened to allow a NH₃ gas as a reaction gas to flow through the gas supply pipe 330. The flow rate of the NH₃ gas is adjusted by the MFC 332. The NH₃ gas is supplied from the gas supply hole 430a of the nozzle 430 into the process chamber 201b and is exhausted from the exhaust pipe 231. At this time, the NH₃ gas is supplied to the wafer 200. In parallel with this, the valve 534 is opened to allow a N₂ gas to flow through the gas supply pipe 530. The flow rate of the N₂ gas flowing through the gas supply pipe 530 is adjusted by the MFC 532. The N₂ gas is supplied into the process chamber 201b together with the NH₃ gas and is exhausted from the exhaust pipe 231. At this time, the valve 524 is opened to allow a N₂ gas to flow through the gas supply pipe 520, thus preventing the NH₃ gas from entering into the nozzle 420. The N₂ gas is supplied into the process chamber 201b via the gas supply pipe 320 and the nozzle 420 and is exhausted from the exhaust pipe 231.

At this time, the internal pressure of the process chamber 201b may be set at a pressure which falls within a range of, for example, 100 to 2,000 Pa, for example, 800 Pa, by adjusting the APC valve 243. The supply flow rate of the NH₃ gas controlled by the MFC 332 may be set at a flow rate which falls within a range of, for example, 0.5 to 5 slm. The supply flow rates of the N₂ gas controlled by the MFCs 522 and 532 may be set at a flow rate which falls within a range of, for example, 1 to 10 slm. The time, during which the NH₃ gas is supplied to the wafer 200, may be set at a time which falls within a range of, for example, 1 to 300 seconds. At this time, the temperature of the heater 207 may be set at the same temperature as that used at the TiCl₄ gas supply step.

The gases flowing through the process chamber 201b at this time are only the NH₃ gas and the N₂ gas. The NH₃ gas is substitution-reacted with at least a portion of the Ti-containing layer formed on the SiN layer of the wafer 200 at the first step described above. During the substitution reaction, Ti contained in the Ti-containing layer and N contained in the NH₃ gas are combined to form a TiN film containing Ti and N on the SiN layer on the wafer 200. That is, no TiN film is formed on the SiO₂ layer on the wafer 200.

### B-4: [Fourth Step]

### (Residual Gas Removal)

After the TiN film is formed, the valve 334 is closed to stop the supply of the NH₃ gas.

Then, the unreacted NH₃ gas, the NH₃ gas contributed to the formation of the TiN film, or the reaction byproduct, which remains within the process chamber 201b, is removed from the interior of the process chamber 201b according to the same process procedures as those of the first step described above.

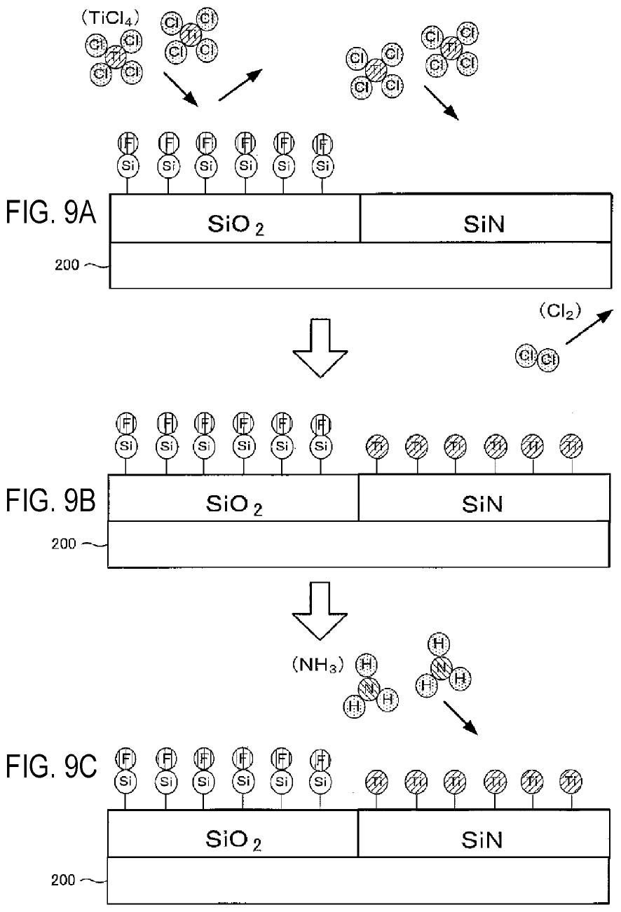

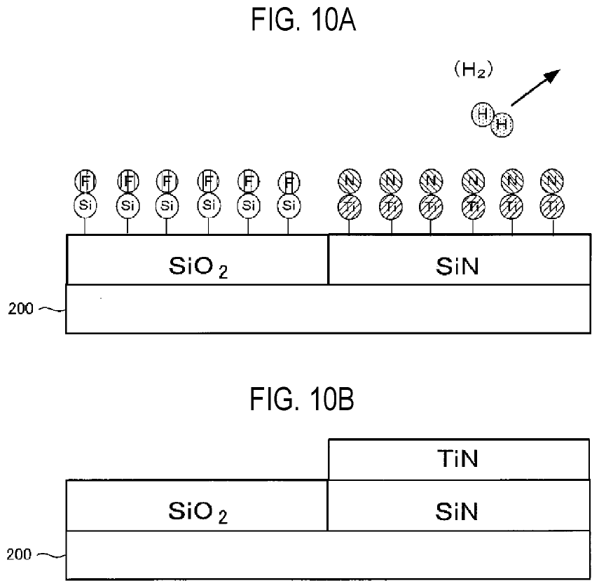

FIGS. 9A to 9C and FIG. 10A show a state in which halogen termination is formed on the SiO₂ layer and halogen termination is not formed on the SiN layer to form a TiN film. FIG. 9A is a model diagram showing a state of a surface of a wafer immediately after a TiCl₄ gas is supplied, FIG. 9B is a model diagram showing a state of the surface of the wafer after exposure with the TiCl₄ gas, and FIG. 9C is a model diagram showing a state of the surface of the wafer immediately after a NH₃ gas is supplied. FIG. 10A is a model diagram showing a state of the surface of the wafer after exposure with the NH₃ gas.

Referring to FIG. 10A, it can be seen that the surface of the SiO₂ layer on the wafer 200 is terminated (halogen-terminated) by the fluorine component on the surface of the wafer 200. Further, it can be seen that a TiN film containing Ti and N is formed on the surface of the SiN layer on the wafer 200. That is, it can be seen that the surface of the SiO₂ layer is halogen-terminated and no TiN film is formed.

### (Performing a Predetermined Number of Times)

Then, a cycle which sequentially performs the first step to the fourth step described above by alternately supplying the TiCl₄ gas as the precursor gas and the NH₃ gas as the reaction gas so as not to be mixed with each other is implemented once or more (a predetermined number of times (n times)), whereby a TiN film having a predetermined thickness (for example, 5 to 10 nm) is formed on the SiN layer of the wafer 200, as illustrated in FIG. 10B. The aforementioned cycle may be repeated multiple times.

Further, in the modification process described above, there has been described a configuration in which a pulse supply is performed by alternately performing the modifying gas supply step (WF₆ gas supply) and the purge step (residual gas removal) a plurality of times has been described, but as seen in FIG. 7B, the modifying gas supply step (WF₆ gas supply) and the purge step (residual gas removal) may be sequentially and consecutively performed once in the process furnace 201a and then the film-forming process described above may be performed in the process furnace 201b, as illustrated in FIG. 7B. Also in FIG. 7B, the loading/unloading operation from the process furnace 202a to the process furnace 202b is omitted.

Further, there has been described above an example in which the TiN film is selectively grown in the aforementioned film-forming temperature zone by using the TiCl₄ gas and the NH₃ gas as the precursor gases used in selective growth, but the present disclosure is not limited thereto and a SiN film may be selectively grown in the range of 400 to 800 degrees C., for example, at a high film-forming temperature of about 500 to 600 degrees C., by using silicon tetrachloride (SiCl₄) and the NH₃ gas as the precursor gases used in selective growth.

An optimum process window exists at the film-forming temperature depending on a kind of a film to be formed, a kind of a gas to be used, a desired film quality, or the like. For example, when the reaction temperature of the gas to be used is 500 degrees C. or higher, a film having a good film quality can be obtained when the film-forming temperature is 500 degrees C. or higher. However, when the temperature is lower than 500 degrees C., the reaction of the gas to be used may not occur, resulting in a film having a poor film quality or a film may not be formed in the first place. Further, when the film-forming temperature is too high and remarkably higher than the autolysis temperature of the precursor gas, the deposition rate may become too high and thus selectivity may be broken or the control of film thickness may be difficult. For example, when the film-forming temperature is 800 degrees C. or higher, selectivity may be broken or the film thickness may not be controlled. Therefore, it is desirable that the film-forming temperature be set at a temperature lower than the autolysis temperature of the precursor gas, such as less than 800 degrees C.

Further, an organic substance and an inorganic substance may be considered as the modifying gases that modifies the surface of the SiO₂ layer on the wafer 200, but surface modification with an organic substance has low heat resistance, such that is the surface modification may be broken when the film-forming temperature reaches 500 degrees C. or higher and the adsorption with Si is also broken. That is, when film formation is performed at a high temperature of 500 degrees C. or higher is performed, selectivity is broken. On the other hand, surface modification with an inorganic substance has high heat resistance, such that the adsorption with Si is not broken even when the film-forming temperature reaches 500 degrees C. or higher. For example, fluorine (F) is a strong passivation agent and has a strong adsorptive power.

Therefore, by using a halide containing an inorganic material containing an inorganic ligand, for example, fluorine (F), chlorine (Cl), iodine (I), bromine (Br), or the like, as the modifying gas that modifies the surface of the SiO₂ layer on the wafer 200, selective growth can be performed by using the modifying gas on even a film for which high-temperature film formation of 500 degrees C. or higher is performed. For example, when high-temperature film formation is performed, the modification process can be performed at a low temperature of 250 degrees C. or lower and the film-forming process which is selective growth can be performed at a high temperature of 500 degrees C. or higher. Among halides, those having a particularly high binding energy may be used in some embodiments. Further, the F-containing gas has the highest binding energy among the halides and has a strong adsorptive power.

Then, a precursor gas having electrically negative molecules is used as the precursor gas used in selective growth. Thus, since the modifying gas that modifies the surface of the SiO₂ layer on the wafer 200 is an electrically negative halide, it repels each other to become difficult to bond with each other. Further, the precursor gas may contain only one precursor molecule such as a metal element or a silicon element in some embodiments. This is because when two or more precursor molecules are contained, for example, when two Si's are contained, a Si—Si bond may be broken, Si and F may be bonded and thus selectivity may be broken.

### (3) EFFECTS ACCORDING TO EMBODIMENTS OF THE PRESENT DISCLOSURE

In the present embodiment, the surface of the SiO₂ layer is first halogen-terminated with the WF₆ gas containing a halide, and then the TiN film is formed on the surface of the SiN layer other than the SiO₂ layer with the TiCl₄ gas containing a halide. The reason is that when the WF₆ gas is exposed, the F molecule is adsorbed on the oxide film and the surface of the oxide film is coated with the F molecule. This F molecule has a strong adsorptive power and is not desorbed even when the film-forming temperature is a high temperature of 500 degrees C. or higher. Further, since the halogen (Cl) contained in the TiCl₄ gas and the halogen (F) on the SiO₂ layer are electrically negative ligands, they become repulsive factors and are not adsorbed on the surface of the SiO₂ layer whose surface is halogen-terminated. Therefore, even when high-temperature film formation of 500 degrees C. or higher is performed, the F coating on the oxide film is not desorbed and can be selectively grown on a surface other than the surface of the SiO₂ layer.

In addition, according to scrutiny of the discloser, it was confirmed that extension of the incubation time by the modifying gas described above for the SiN film, the Si film, the metal film, and the metal oxide film is shorter than that for the SiO₂ film. By using this difference in the incubation time, a film is difficult to be formed on the SiO₂ film and can be selectively formed on other films.

That is, according to the present embodiment, it is possible to provide a technique capable of selectively forming a film on a substrate.

### (4) OTHER EMBODIMENTS

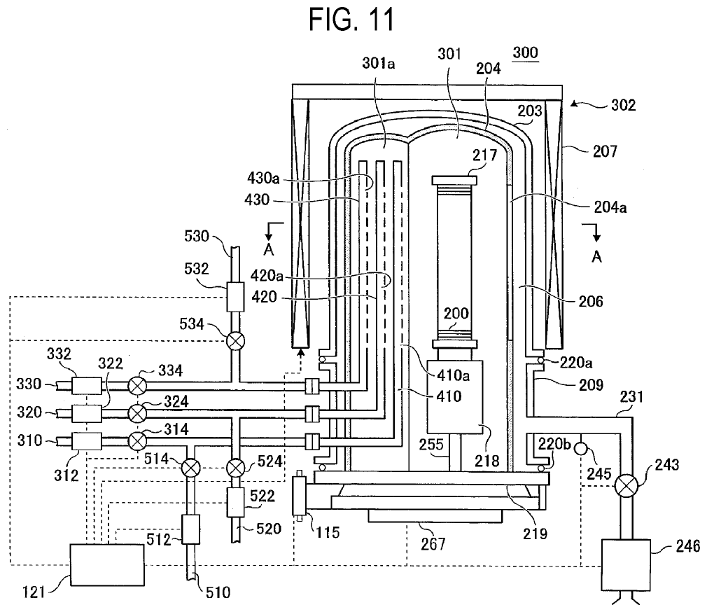

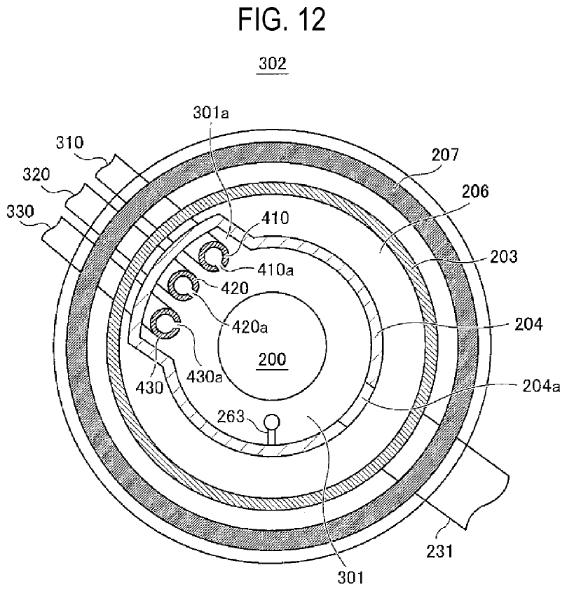

In the aforementioned embodiments, there have been described the configurations in which the modification process and the film-forming process are performed in separate process chambers by using the cluster-type substrate processing apparatus 10 including the process chamber 201a in which the modification process is performed and the process chamber 201b in which the film-forming process is performed, but may be similarly applied to a configuration in which the modification process and the film-forming process are performed in the same process chamber 201 by using a substrate processing apparatus 300 including a modifying gas supply system and a deposition gas supply system in one process chamber 301, as illustrated in FIGS. 11 and 12. That is, the present disclosure may be similarly applied to a configuration in which substrate processing is performed in situ. In this case, the modification process and the film-forming process may be continuously performed. That is, the film-forming process may be continuously performed without unloading the wafer 200 to the outside of the process chamber after the modification process. Thus, the film-forming process can be further performed while maintaining the F termination formed on the surface of the SiO₂ layer, compared with the aforementioned embodiments.

As specific substrate processing, as the modification process, the wafer loading, and the pressure regulation and temperature adjustment are performed, the modifying gas supply step and the purge step are performed a predetermined number of times, and then the after-purge is performed. Thereafter, consecutively, as the film-forming process, the pressure regulation and temperature adjustment are performed, the first to fourth steps are performed a predetermined number of times, and then the after-purge and the atmospheric pressure return are performed and the wafer unloading is performed.

Further, in the aforementioned embodiments, there has been described the case where the modification process and the film-forming process are performed once, but the modification process and the film-forming process may be alternately repeated multiple times. In this case, the substrate processing (the process of manufacturing a semiconductor device) includes performing a process a predetermined number of times, the process including alternately performing: a step of supplying a modifying gas containing an inorganic ligand (for example, a WF₆ gas) to a wafer 200 including a first surface (for example, a SiO₂ layer) and a second surface (for example, a SiN layer) to modify the first surface; and a step of supplying a precursor gas (for example, a TiCl₄ gas) and a reaction gas (for example, a NH₃ gas) as a deposition gas to the wafer 200 to selectively grow a film (for example, a TiN film) on the second surface.

When the modification process and the film-forming process are alternately repeated multiple times, even when F termination formed on the first surface during the film-forming process is gradually desorbed and a film is formed on the first surface to break selectivity, the formed film can be removed by etching with the modifying gas in the modification process to repair the desorbed F-termination. That is, the second modification process also has an action as an etching process. It is possible to improve the selectivity by performing the film-forming process after repairing the desorbed F-termination.

Further, in the aforementioned embodiments, there has been described the case where the tungsten hexafluoride (WF₆) gas is used as the modifying gas, but the present disclosure is not limited thereto. The present disclosure may be similarly applied to a case where another gas such as a chlorine trifluoride (ClF₃) gas, a nitrogen trifluoride (NF₃) gas, a hydrogen fluoride (HF) gas, or a fluorine (F₂) gas is used as the modifying gas. When metal contamination is concerned, a gas containing no metal element may be used.

Similarly, in the aforementioned embodiments, there has been described the case where the TiCl₄ gas is used as the precursor gas used in selective growth, but the present disclosure is not limited thereto. The present disclosure may be similarly applied to a case where another gas such as silicon tetrachloride (SiCl₄), aluminum tetrachloride (AlCl₄), zirconium tetrachloride (ZrCl₄), hafnium tetrachloride (HfCl₄), tantalum pentachloride (TaCl₅), tungsten pentachloride (WCl₅), molybdenum pentachloride (MoCl₅), or tungsten hexachloride (WCl₆) containing halogen is used as the precursor gas.

Similarly, in the aforementioned embodiments, there has been described the case where the NH₃ gas is used as the reaction gas used in selective growth, but the present disclosure is not limited thereto. The present disclosure may be similarly applied to a case where another gas such as hydrazine (N₂H₄), water (H₂O), oxygen (O₂), or a gaseous mixture of hydrogen (H₂) and oxygen (O₂) reacting with the precursor gas is used as the reaction gas.

Further, when a ClF₃ gas is used as the modifying gas, a SiN film can be selectively grown at a high temperature of about 550 degrees C. by using silicon tetrachloride (SiCl₄) and a NH₃ gas as the precursor gas used in selective growth. Further, a SiO₂ film can be selectively grown at an extremely low temperature of about 40 to 90 degrees C. by using silicon tetrachloride (SiCl₄) as the precursor gas used in selective growth, a H₂O gas and a catalyst such as pyridine.

Although various exemplary embodiments of the present disclosure have been described above, the present disclosure is not limited to the embodiments but may be used in combination as appropriate.

### (5) EXAMPLES

### Example 1

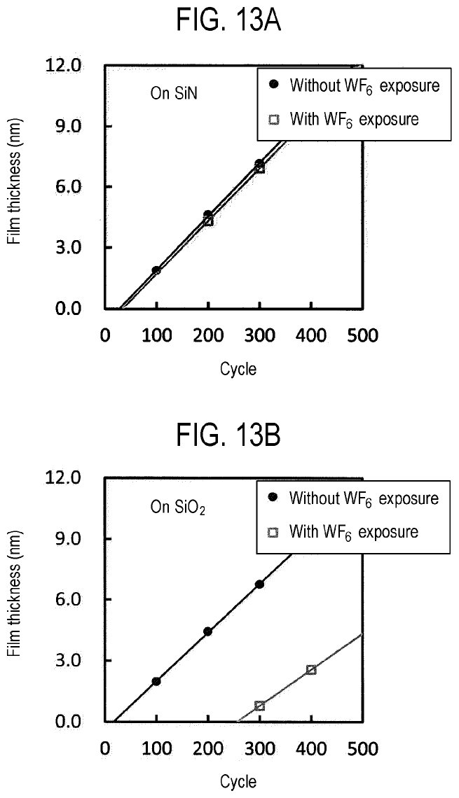

Next, a difference in a film thickness of a TiN film formed when a SiN layer is exposed to a WF₆ gas as a modifying gas to form the titanium nitride (TiN) film on the SiN layer and a film thickness of the TiN film formed when the TiN film is formed on the SiN layer while the SiN layer is not exposed to the WF₆ gas by using the substrate processing apparatus 10 described above and the substrate processing described above will be described with reference to FIG. 13A.

As shown in FIG. 13A, it is confirmed that there is almost no difference in the thickness of the film formed on the surface of the SiN layer as an underlying film, between when the SiN layer is exposed to the WF₆ and when the SiN layer is not exposed to the WF₆, and the film thickness of the TiN film is increased depending on the number of process cycles. That is, it is confirmed that the TiN film is formed on the surface of the SiN layer regardless of the presence or absence of exposure to the WF₆. It is considered that this is because the surface of the SiN layer is not halogen-terminated, as illustrated in FIG. 8C.

Next, a difference in a film thickness of a TiN film formed when a SiO₂ layer is exposed to a WF₆ gas to form a TiN film on the SiO₂ layer in the substrate processing described above and a film thickness of the TiN film formed when the TiN film is formed on the SiO₂ layer while the SiO₂ layer is not exposed to the WF₆ gas by using the substrate processing apparatus 10 described above will be described with reference to FIG. 13B.

It is confirmed that, when the SiO₂ layer is exposed to the WF₆, the TiN film is not formed on the surface of the SiO₂ layer as an underlying film, unless the aforementioned substrate processing is repeated for 256 cycles or more. On the other hand, it is confirmed that, when the SiO₂ layer is not exposed to the WF₆ gas, the TiN film is formed on the surface of the SiO₂ layer as the underlying film, when the aforementioned substrate processing is repeated for 16 cycles or more. That is, it is confirmed that an incubation time is lengthened by exposing the SiO₂ layer to the WF₆ gas.

### Example 2

Next, a film thickness T_{SiN} where the TiN film may be preferentially formed on the SiN layer compared to the SiO₂ layer is defined by the following equation.

T_{SiN}=deposition rate on SiN layer×(incubation time on SiO₂ layer-incubation time on SiN layer) Eq. (1)

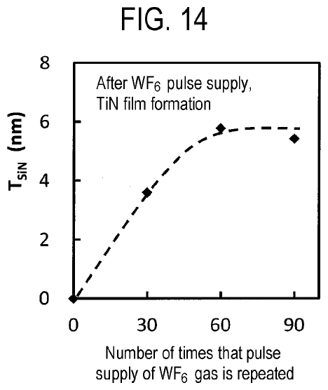

In the presence of exposure with the WF₆ in FIG. 13A described above as an example, the deposition rate of the TiN film on the SiN layer is 0.26 nm/cycle, the incubation time on the SiN layer is 33 cycles, and the incubation time on the SiO₂ layer is 256 cycles; and therefore, T_{SiN}=5.8 nm is calculated by Eq. (1). That is, the TiN film of 5.8 nm can be selectively formed on the SiN layer without forming the TiN film on the SiO₂ layer. FIG. 14 shows dependence of T_{SiN} on the number of times that the pulse supply of the WF₆ gas is repeated.

As shown in FIG. 14, it can be seen that T_{SiN} shows a saturation tendency when the pulse supply of the WF₆ gas is repeated about 60 times.

### Example 3

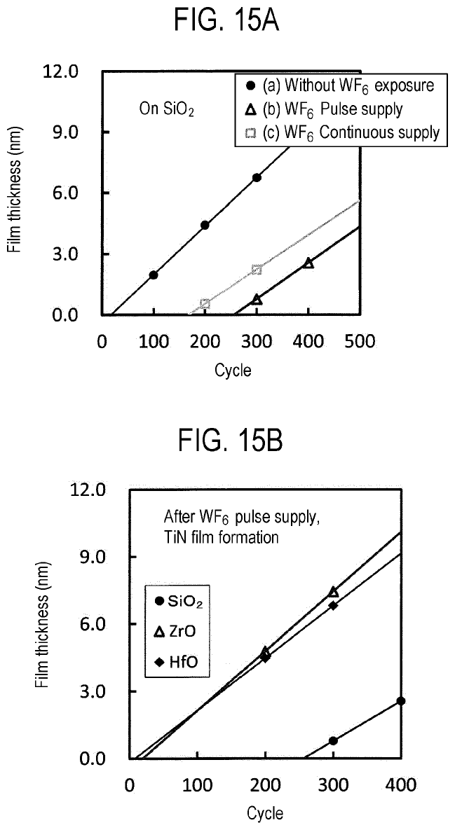

Next, a difference in film thicknesses of TiN films formed (a) when the TiN film is formed on a SiO₂ layer while the SiO₂ layer is not exposed to a WF₆ gas, (b) when the WF₆ gas is pulse-supplied to form the TiN film on the SiO₂ layer, and (c) when the WF₆ gas is continuously supplied to form the TiN film on the SiO₂ layer in the substrate processing described above by using the substrate processing apparatus 10 described above will be described with reference to FIG. 15A. The pulse supply of the WF₆ gas is set to 60 cycles (a total exposure time of the WF₆ gas is 10 minutes) in the pulse supply of (b), and the exposure time of the WF₆ gas is set to 10 minutes in the continuous supply of (c) so that the total exposure time of (b) becomes equal to that of (c).

It is confirmed that the incubation time is 16 cycles when the SiO₂ layer is not exposed to the WF₆ gas in (a), the incubation time is 256 cycles in the pulse supply of (b), the incubation time is 168 cycles in the continuous supply of (c), and the incubation time when the SiO₂ layer is exposed to the WF₆ gas in (b) and (c) is longer than that when the SiO₂ layer is not exposed to the WF₆ gas in (a). Further, it is confirmed that, even when the total exposure amount of the WF₆ gas is equal, the incubation time when the WF₆ gas is pulse-supplied in (b) is longer than that when the WF₆ gas is continuously supplied in (c). It is considered that this is because reaction byproducts of reaction between the WF₆ gas and the surface of the SiO₂ layer are removed from the surface of the SiO₂ layer by pulse-supplying the WF₆ gas and inserting the purge step during the exposure to the WF₆ gas and therefore the surface is modified, such that the incubation time became lengthened even at the same exposure amount.

### Example 4

Next, a WF₆ gas is pulse-supplied (60 cycles) to a SiO₂ layer, a zirconium oxide (ZrO) layer, and a hafnium oxide (HfO) layer to form TiN films in the substrate processing described above by using the substrate processing apparatus 10 described above, and then a difference in film thicknesses of the formed TiN films will be described with reference to FIG. 15B.

As shown in FIG. 15B, it is confirmed that the incubation times of the TiN films formed on the ZrO layer and the HfO layer are shorter than the incubation time of the TiN film formed on the SiO₂ layer, even when the layers are exposed to the WF₆ gas. That is, it is confirmed that the incubation times on the ZrO layer and the HfO layer are shorter than the incubation time on the SiO₂ layer, and the TiN film can be preferentially formed on the ZrO layer and the HfO layer, as compared with the SiO₂ layer.

### Example 5

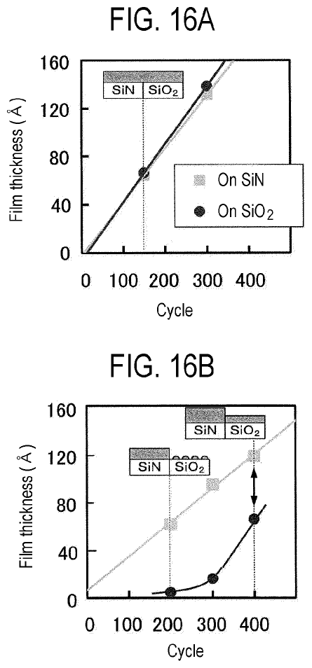

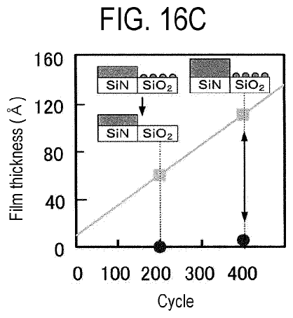

Next, an effect of the modification process on a selectivity when a modification process is performed at 250 degrees C. by using a ClF₃ gas as the modifying gas, and a film-forming process in which a SiN film is selectively grown on a SiN layer of a wafer having the SiN layer and a SiO₂ layer formed thereon at 500 degrees C. is performed in the substrate processing described above by using the substrate processing apparatus 10 described above will be explained with reference to FIGS. 16A to 16C. FIG. 16A is a comparative example and is a diagram showing a film thickness of the SiN film selectively grown on each of the SiN layer and the SiO₂ layer when the film-forming process is performed without performing the modification process. In FIG. 16A, a case where the film-forming process is performed for 150 cycles and a case where the film-forming process is performed for 300 cycles are plotted. FIG. 16B is a diagram showing a film thickness of the SiN film selectively grown on each of the SiN layer and the SiO₂ layer when the film-forming process is performed after the modification process. In FIG. 16B, cases where the film-thickness process is performed for 200 cycles, 300 cycles, and 400 cycles are plotted. FIG. 16C is a diagram showing a film thickness of the SiN film selectively grown on each of the SiN layer and the SiO₂ layer when the modification process and the film-forming are alternately performed twice. In FIG. 16C, cases where each film-forming process is performed for 200 cycles (400 cycles in total) are plotted.

As shown in FIG. 16A, it is confirmed that there is no difference in the film thickness of the SiN film formed on the SiN layer and the SiO₂ layer when the film-forming process is performed without performing the modification process and thus almost no selectivity is generated. Further, as illustrated in FIGS. 16B and 16C, it is confirmed that selectivity is generated between the SiN layer and the SiO₂ layer by performing the modification process before the film-forming process, and more remarkable selectivity is generated by alternately repeating the modification process and the film-forming process multiple times.

According to the present disclosure, it is possible to selectively form a film on a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of manufacturing a semiconductor device, comprising:
modifying a first surface of a substrate by supplying a modifying gas containing an inorganic ligand to the substrate including the first surface and a second surface different from the first surface; and
selectively growing a film on the second surface by supplying a deposition gas to the substrate.

2. The method according to claim 1, wherein the modifying gas is a first halide.

3. The method according to claim 2, wherein the first halide is a fluorine-containing gas.

4. The method according to claim 1, wherein the deposition gas includes a precursor gas and a reaction gas reacting with the precursor gas, and
wherein, in the act of selectively growing the film on the second surface, the precursor gas and the reaction gas are alternately supplied so that the precursor gas and the reaction gas are not mixed with each other.

5. The method according to claim 2, wherein the deposition gas includes a precursor gas and a reaction gas reacting with the precursor gas, and
wherein, in the act of selectively growing the film on the second surface, the precursor gas and the reaction gas are alternately supplied so that the precursor gas and the reaction gas are not mixed with each other.

6. The method according to claim 3, wherein the deposition gas includes a precursor gas and a reaction gas reacting with the precursor gas, and
wherein, in the act of selectively growing the film on the second surface, the precursor gas and the reaction gas are alternately supplied so that the precursor gas and the reaction gas are not mixed with each other.

7. The method according to claim 4, wherein the precursor gas is a second halide.

8. The method according to claim 5, wherein the precursor gas is a second halide.

9. The method according to claim 6, wherein the precursor gas is a second halide.

10. The method according to claim 7, wherein the second halide is a chlorine-containing gas.

11. The method according to claim 4, wherein the modifying gas and the precursor gas each have a ligand which is electrically negative.

12. The method according to claim 1, wherein the act of selectively growing the film on the second surface is performed while heating the substrate at 500 degrees C. or higher.

13. The method according to claim 1, wherein the act of modifying the first surface is performed while heating the substrate at 300 degrees C. or lower.

14. The method according to claim 12, wherein the act of modifying the first surface is performed while heating the substrate at 300 degrees C. or lower.

15. The method according to claim 1, wherein the first surface is a silicon oxide layer.

16. A substrate processing apparatus, comprising:
a process chamber configured to accommodate a substrate;
a first gas supply system configured to supply a modifying gas containing an inorganic ligand to the process chamber;
a second gas supply system configured to supply a deposition gas to the process chamber; and
a controller configured to be capable of controlling the first gas supply system and the second gas supply system to perform a process, the process comprising:
modifying a first surface of the substrate by supplying the modifying gas to the process chamber accommodating the substrate including the first surface and a second surface different from the first surface; and
selectively growing a film on the second surface by supplying the deposition gas to the process chamber.

17. A non-transitory computer-readable recording medium recording a program that causes, by a computer, a substrate processing apparatus to perform a process, the process comprising:
modifying a first surface of a substrate by supplying a modifying gas containing an inorganic ligand to the substrate accommodated in a process chamber of the substrate processing apparatus, the substrate including the first surface and a second surface different from the first surface; and
selectively growing a film on the second surface by supplying a deposition gas to the substrate.
